(19) United States
(12) Patent Application Publication
(10) Pub. No.: US 2012/0275244 A1
(43) Pub. Date: Nov. 1, 2012

(54) SEMICONDUCTOR INTEGRATED CIRCUIT AND SEMICONDUCTOR MEMORY DEVICE HAVING FUSE CIRCUIT

(76) Inventor: Chang-Ho DO, Gyeonggi-do (KR)

(21) Appl. No.: 13/313,370

(22) Filed: Dec. 7, 2011

(30) Foreign Application Priority Data
Apr. 28, 2011 (KR) 10-2011-0040350

(51) Int. Cl. G11C 17/16; G11C 7/00

(52) U.S. Cl. 365/189.11; 365/225.7

(57) ABSTRACT

A semiconductor integrated circuit includes: a fuse; a first driving unit configured to drive a sensing node in response to a first fuse sensing signal; a second driving unit configured to drive the sensing node in response to a second fuse sensing signal, wherein the second driving unit and the fuse form a driving path; a bypass resistor unit connected in parallel with the fuse; and a sensing unit configured to sense a programming state of the fuse in response to a voltage of the sensing node.

### CROSS-REFERENCE TO RELATED APPLICATIONS

The present application claims priority of Korean Patent Application No. 10-2011-0040350, filed on Apr. 28, 2011, which is incorporated herein by reference in its entirety.

### BACKGROUND

1. Field

Exemplary embodiments of the present invention relate to a semiconductor integrated circuit design technology, and more particularly, to a fuse circuit of a semiconductor integrated circuit.

2. Description of the Related Art

A semiconductor integrated circuit includes circuits of the same patterns, and redundancy circuits are disposed in the semiconductor integrated circuit so that the semiconductor integrated circuit can be sorted as a good product even though fails have occurred in some circuits due to process variants.

In detail, in the case of a semiconductor memory device, a large number of memory cells are integrated in one chip. If a fail occurs in any one of the memory cells, the corresponding memory chip is sorted as a bad product and cannot be used.

As a semiconductor integrated circuit is highly integrated, a gradually increasing number of memory cells are integrated in a chip with a limited size. In this regard, if the entire memory chip is sorted as a bad product when a fail occurs in any one cell, the number of memory chips to be discarded will markedly increase, and due to this fact, mass-producing a semiconductor memory device with economic efficiency may be very difficult.

To efficiently mass-produce a semiconductor memory device, a conventional semiconductor memory device has a fuse circuit and a redundancy cell array. The fuse circuit includes a plurality of fuses each having the shape of a metal line, and a failed cell is replaced with a redundancy cell in a repair process depending upon whether or not a fuse is blown. The redundancy cell array and the fuse circuit are formed during a semiconductor manufacturing processes. The repair process, which replaces the failed memory cell with the redundancy cell, is performed to selectively cut a fuse constituted by a metal line mainly through using a laser beam.

Even after the fuse is blown, a fail is likely to occur again because the cut fuse may be connected again due to electrical and chemical migration phenomena by metal ions. Such a fail is generally called a HAST (highly accelerated stress testing) fail. The HAST fail frequently occurs because aluminum, which is the material of a metal line, is replaced with copper. The HAST fail mainly occurs when testing reliability under a condition including a high temperature, a high voltage, and 100% of moisture.

While the HAST fail occurs as copper is used for the manufacture of a semiconductor integrated circuit to operate at a high speed, the HAST fail may also occur where aluminum or other materials are used. Since the HAST fail occurs after blowing a fuse in a repair process, finding and also repairing the HAST fail may be difficult. The HAST fail serves as a factor that deteriorates the productivity and the reliability of a semiconductor integrated circuit.

FIGS. 1A and 1B are diagrams illustrating a conventional fuse circuit of a semiconductor integrated circuit, wherein FIG. 1A illustrates a state where a fuse is not blown and FIG. 1B illustrates a state where a fuse is blown.

Referring to FIG. 1A, a conventional fuse circuit of a semiconductor integrated circuit includes an NMOS transistor MNO, a PMOS transistor MPO, a fuse FUSE, an inverter IV0, and an NMOS transistor MN1. The NMOS transistor MNO has a source that is connected to a ground voltage VSS, a drain that is connected to a sensing node A, and a gate that receives a fuse sensing signal IN1. The PMOS transistor MPO has a source that is connected to a power supply terminal VDD, a drain that is connected to node B, and a gate that receives the fuse sensing signal IN1. The fuse FUSE is connected between the node B and the sensing node A. The inverter IV0 has an input terminal connected to the sensing node A and an output terminal for outputting an output signal OUT. The NMOS transistor MN1 has a source that is connected to the ground voltage VSS, a drain that is connected to the sensing node A, and a gate that receives the output signal OUT.

The NMOS transistor MN1 constitutes an inverting latch together with the inverter IV0.

Operations of the fuse circuit shown in FIGS. 1A and 1B will be described below.

First, the fuse sensing signal IN1 has a logic high level in an initial state. Accordingly, the NMOS transistor MN0 is turned on and discharges the sensing node A. As a result, the output signal OUT is outputted at a logic high level. The NMOS transistor MN1 constituting the latch is turned on such that the state of the sensing node A is maintained.

Thereafter, if the fuse sensing signal IN1 is activated to a logic low level, the NMOS transistor MN0 is turned off, and the PMOS transistor MP0 is turned on. At this time, fuse state discrimination is implemented by the pull-down capability of the NMOS transistor MN1 for maintaining the initial state and the pull-up capability of the PMOS transistor MP0 and the fuse FUSE. Where the fuse FUSE is not blown (see FIG. 1A), the sensing node A is driven to the power supply voltage VDD through the PMOS transistor MP0 and the fuse FUSE. Transition of the sensing node A is determined by a ratio between the effective resistance of a pull-up device and the effective resistance of a pull-down device. If the voltage level of the sensing node A rises higher than the threshold logic voltage of the inverter IV0, the output signal OUT transitions to a logic low level, and as the output signal OUT is fed back, the NMOS transistor MN1 of the pull-down device is turned off and stabilizes the level of the sensing node A. As a consequence, the output signal OUT becomes a logic high level.

Conversely, where the fuse FUSE is blown (see FIG. 1B), while the PMOS transistor MP0 is in a turned-on state, since the fuse FUSE is in a blown state, the output signal OUT maintains a logic high level.

The following Table 1 represents logic level changes in the respective nodes of the fuse circuit shown in FIGS. 1A and 1B depending upon the fuse sensing signal IN1 and a state of the fuse FUSE. The logic level changes are the same as described in the above explanation of the operations.

TABLE 1

| | | | |
|---|---|---|---|
| | IN1 | H | L |
| Fuse No Cut | Node B | L | H |
| | Node A | L | H |
| | OUT | H | L |
| Fuse Cut | Node B | Floating | H |
| | Node A | L | L |
| | OUT | H | H |

Referring to Table 1, Table 1 shows that, in the case where the fuse sensing signal IN1 is activated to a logic low level, the logic level of the output signal OUT is changed depending upon whether the fuse FUSE is cut or not.

However, when the fuse FUSE is cut, a voltage of VDD-VSS is applied between the node B and the sensing node A with the fuse sensing signal IN1 having a logic low level, and a corresponding electric field promotes electrical and chemical migration phenomena of metal ions as aforementioned above.

The electrical and chemical migration phenomena of the metal ions cause the cut fuse FUSE to be connected again, which reverses a fuse programming result and leads to an error in the operations of the integrated circuit.

While the electrical and chemical migration phenomena of the metal ions result from changes in processing, since the electrical and chemical migration phenomena is difficult to prevent in terms of processing, technologies for preventing the electrical and chemical migration phenomena in terms of design have been suggested. A typical example of such technologies is disclosed in U.S. Pat. No. 6,021,078. In this technology, potentials of both ends of a fuse are maintained the same so that the electrical and chemical migration phenomena of metal ions are prevented. Nevertheless, because a fuse circuit is configured by circuit elements, the number of which is two times greater than that of a basic fuse circuit, a substantial increase in a circuit area is caused in a semiconductor integrated circuit. In a semiconductor memory device that uses a large number of fuse circuits, productivity of the semiconductor integrated circuit cannot help but deteriorate because of the additional circuit area for the larger fuse circuits.

### SUMMARY

Embodiments of the present invention are directed to a semiconductor integrated circuit and a semiconductor memory device that can prevent electrical and chemical migration phenomena of metal ions forming a fuse while minimizing an increase in the number of circuit elements constituting a fuse circuit.

In accordance with an embodiment of the present invention, a semiconductor integrated circuit includes: a fuse; a first driving unit configured to drive a sensing node in response to a first fuse sensing signal; a second driving unit configured to drive the sensing node in response to a second fuse sensing signal, wherein the second driving unit and the fuse form a driving path; a bypass resistor unit connected in parallel with the fuse; and a sensing unit configured to sense a programming state of the fuse in response to a voltage of the sensing node.

In accordance with another embodiment of the present invention, a semiconductor integrated circuit includes: a fuse; an NMOS transistor configured to pull-down drive a sensing node in response to a first fuse sensing signal; a PMOS transistor configured to pull-up drive the sensing node in response to a second fuse sensing signal, wherein the PMOS transistor and the fuse form a driving path; a bypass resistor unit connected in parallel with the fuse; and a sensing unit configured to sense a programming state of the fuse in response to a voltage of the sensing node.

In accordance with another embodiment of the present invention, a semiconductor integrated circuit includes: a fuse; an NMOS transistor configured to pull-down drive a sensing node in response to a first fuse sensing signal; a first PMOS transistor configured to pull-up drive the sensing node in response to a second fuse sensing signal; a second PMOS transistor configured to pull-up drive the sensing node in response to the first fuse sensing signal, wherein the first and second PMOS transistor and the fuse form a driving path; a bypass resistor unit connected in parallel with the fuse; and a sensing unit configured to sense a programming state of the fuse in response to a voltage of the sensing node.

In accordance with another embodiment of the present invention, a semiconductor integrated circuit includes: a fuse; a PMOS transistor configured to pull-up drive a sensing node in response to a first fuse sensing signal; an NMOS transistor configured to pull-down drive the sensing node in response to a second fuse sensing signal, wherein the NMOS transistor and the fuse form a driving path; a bypass resistor unit connected in parallel with the fuse; and a sensing unit configured to sense a programming state of the fuse in response to a voltage of the sensing node.

In accordance with yet another embodiment of the present invention, a semiconductor integrated circuit includes: a fuse; a PMOS transistor configured to pull-up drive a sensing node in response to a first fuse sensing signal; a first NMOS transistor configured to pull-down drive the sensing node in response to a second fuse sensing signal; a second NMOS transistor the first NMOS transistor and configured to pull-down drive the sensing node in response to the first fuse sensing signal, wherein the first and second NMOS transistor and the fuse form a driving path; a bypass resistor unit connected between both ends of the fuse; and a sensing unit configured to sense a programming state of the fuse in response to a voltage of the sensing node.

In accordance with still another embodiment of the present invention, a semiconductor memory device includes: a plurality of fuses; a first driving unit configured to pull-up drive a common sensing node in response to a precharge signal; a plurality of second driving units configured to pull-down drive the common sensing node in response to corresponding address information, wherein the plurality of second driving units and corresponding fuses form driving paths; a plurality of bypass resistor units connected in parallel with corresponding fuses; and a sensing unit configured to sense a programming state of each of the plurality of fuses in response to a voltage of the common sensing node.

### BRIEF DESCRIPTION OF THE DRAWINGS

FIGS. 1A and 1B are diagrams illustrating a conventional fuse circuit of a semiconductor integrated circuit.

FIG. 2 is a diagram illustrating a fuse circuit in accordance with a first embodiment of the present invention.

FIG. 3A is a view illustrating the wave forms of first and second fuse sensing signals in FIG. 2.

FIG. 3B is a view illustrating other exemplary wave forms of the first and second fuse sensing signals in FIG. 2.

FIG. 4 is a DC characteristic curve of an inverter.

FIG. 5A is a view illustrating a state of elements that determine the voltage level of a sensing node with a fuse not cut.

FIG. 5B is a view illustrating another state of the elements that determine the voltage level of the sensing node with the fuse cut.

FIG. 6 is a diagram illustrating a fuse circuit in accordance with a second embodiment of the present invention.

FIG. 7 is a diagram illustrating a fuse circuit in accordance with a third embodiment of the present invention.

FIG. 8 is a diagram illustrating a fuse circuit in accordance with a fourth embodiment of the present invention.

FIG. 9 is a diagram illustrating a fuse circuit in accordance with a fifth embodiment of the present invention.

FIG. 10 is a view illustrating the wave forms of first and second fuse sensing signals in FIG. 9.

FIG. 11 is a view illustrating a state of elements which determine the voltage level of a sensing node with a fuse not cut in FIG. 9.

FIG. 12 is a diagram illustrating a fuse circuit in accordance with a sixth embodiment of the present invention.

FIG. 13 is a view illustrating operation timings when the fuse circuit of FIG. 12 is applied to a redundancy circuit of a DRAM.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

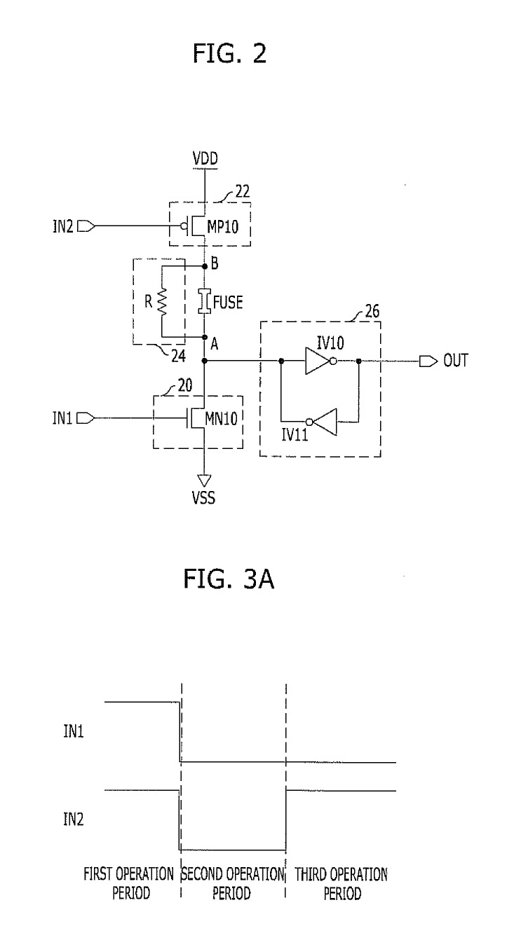

FIG. 2 is a diagram illustrating a fuse circuit in accordance with a first embodiment of the present invention.

Referring to FIG. 2, a fuse circuit in accordance with a first embodiment of the present invention includes a fuse FUSE, a first driving unit 20 configured to drive a sensing node A in response to a first fuse sensing signal IN1, a second driving unit 22 forming a driving path together with the fuse FUSE and configured to drive a sensing node A in response to a second fuse sensing signal IN2, a bypass resistor unit 24 connected between both ends of the fuse FUSE, and a sensing unit 26 configured to sense a programming state of the fuse FUSE in response to a voltage applied to the sensing node A.

The fuse FUSE and the bypass resistor unit 24 may be disposed anywhere on a pull-up path, and may be disposed on a pull-down path as the occasion demands.

The detailed circuit configuration of the fuse circuit exemplified in FIG. 2 will be described below.

The first driving unit 20 includes an NMOS transistor MN10 having a source that is connected to a ground voltage VSS, a drain that is connected to the sensing node A, and a gate that receives the first fuse sensing signal IN1.

The second driving unit 22 includes a PMOS transistor MP10 having a source that is connected to a power supply terminal VDD, a drain that is connected to a node B, and a gate that receives the second fuse sensing signal IN2.

The fuse FUSE is connected between node B and the sensing node A, and the bypass resistor unit 24 includes a resistor R that is connected between the node B and the sensing node A in parallel to the fuse FUSE.

The sensing unit 26 includes an inverter IV10 that has an input terminal connected to the sensing node A and outputs an output signal OUT, and an inverter IV11 that receives the output signal OUT and has an output terminal connected to the sensing node A.

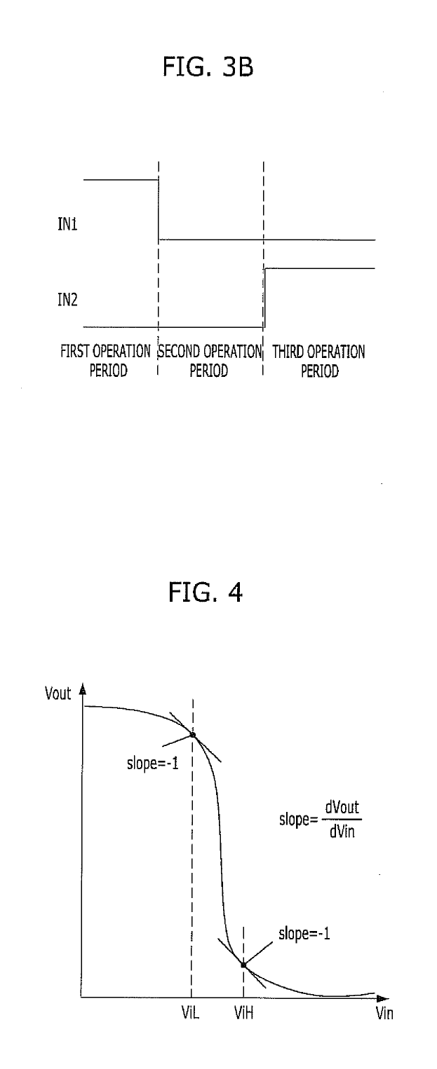

FIG. 3A shows the wave forms of the first and second fuse sensing signals IN1 and IN2 in FIG. 2, and the following Table 2 represents voltage changes in the respective nodes of the fuse circuit shown in FIG. 2 depending upon the first and second fuse sensing signals IN1 and IN2 and a state of the fuse FUSE. Operations of the fuse circuit shown in FIG. 2 will be explained with reference to FIG. 3A and Table 2.

TABLE 2

| | | | | |
|---|---|---|---|---|
| | IN1 | H | L | L |
| | IN2 | H | L | H |
| Fuse No Cut | Node B | VSS | Vb | VDD |
| | Node A | VSS | Va | VDD |
| | OUT | VDD | ~VSS | VSS |
| Fuse Cut | Node B | VSS | Vb | VSS |
| | Node A | VSS | Va | VSS |
| | OUT | VDD | ~VDD | VDD |

First, in an initialization period (a first operation period) of the fuse circuit, the first and second fuse sensing signals IN1 and IN2 are both deactivated to a logic high level. At this time, the NMOS transistor MN10 is turned on to discharge the sensing node A, and the output signal OUT becomes a logic high level.

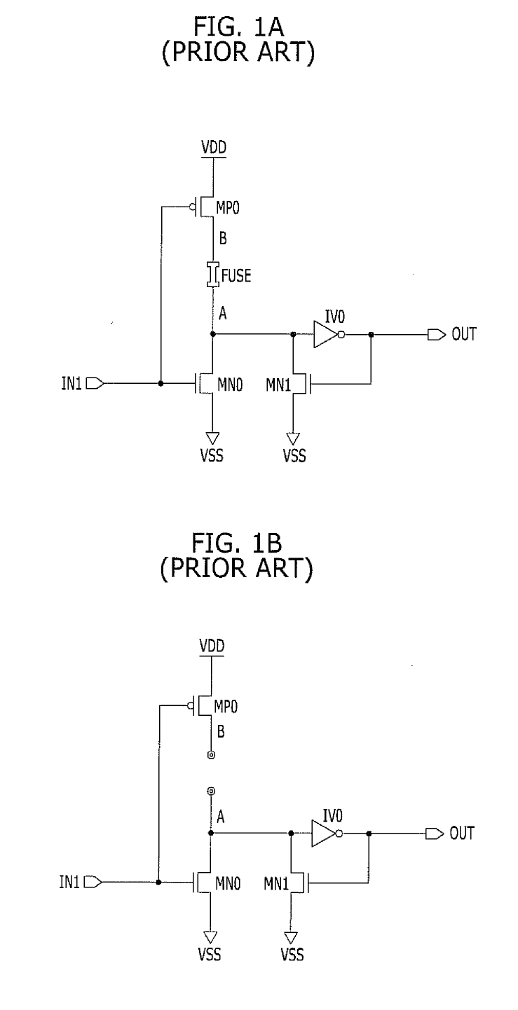

Next, in a fuse state sensing period (a second operation period) of the fuse circuit, the first and second fuse sensing signals IN1 and IN2 are both activated to a logic low level. Accordingly, the NMOS transistor MN10 is turned off and the PMOS transistor MP10 is turned on. Also, the pull-down NMOS transistor of the inverter IV11 continues driving for maintaining an initial value.

Where the fuse is not cut, the PMOS transistor MP10 performs pull-up driving for the sensing node A, and the pull-down NMOS transistor of the inverter IV11 performs pull-down driving for the sensing node A. More specifically, transition of the sensing node A is effected depending upon a ratio between the effective resistance value of pull-up devices (the PMOS transistor MP10, the fuse FUSE and the resistor R) and the effective resistance value of the pull-down device (the pull-down NMOS transistor of the inverter IV11). If a voltage level Va of the sensing node A becomes higher than a threshold logic value ViH of the inverter IV10 (Va>ViH) for a stable operation, the output signal OUT becomes a logic low level. The output signal OUT is fed back and turns on the PMOS transistor of the inverter IV11 such that the sensing node A can stably maintain a logic high level. This operation is not different from the operation of the fuse circuit shown in FIG. 1. Since the resistor R is connected in parallel to the fuse FUSE, the effective resistance of the pull-up devices decreases, and thus, the connection state of the fuse FUSE may be stably sensed.

Where the fuse FUSE is cut, while both ends of the fuse FUSE are actually not in an insulated state because both ends of the fuse FUSE are connected by the resistor R (for reference, a cut fuse has ideally a very high resistance value and has usually a resistance value equal to or greater than 1 MΩ), the voltage level Va of the sensing node A does not become unconditionally a logic low level. As described above, the voltage level Va of the sensing node A is determined by the ratio between the effective resistance value of the pull-up devices (the PMOS transistor MP10, the fuse FUSE and the resistor R) and the effective resistance value of the pull-down device (the pull-down NMOS transistor of the inverter IV11). As the voltage level Va of the sensing node A determined in this way is kept lower than the threshold logic voltage of the inverter IV10 (Va<ViL) for a stable operation, the output signal OUT becomes a logic high level and represents the cut state of the fuse FUSE.

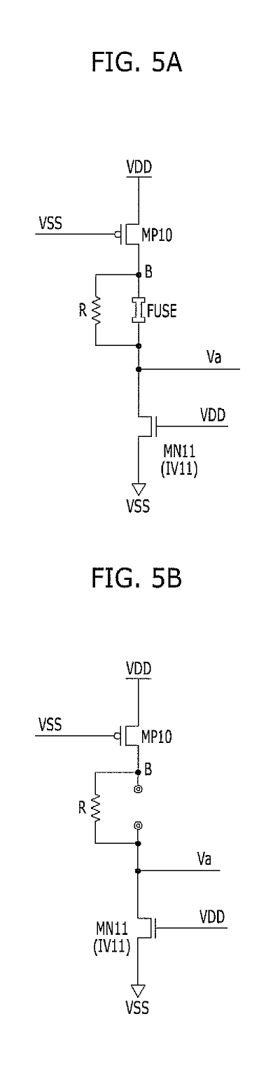

The relationship between the DC characteristic curve (FIG. 4) of the inverter IV10 and the voltage level Va of the sensing node A for ensuring a stable output of the fuse circuit in the second operation period despite the presence of the resistor R will be described below. FIGS. 5A and 5B illustrate states of elements that determine the voltage level Va of the sensing node A with the fuse FUSE not cut and with the fuse FUSE cut, respectively.

Referring to FIG. 5A, where the fuse FUSE is not cut, the ratio between the effective resistance value of the turned-on PMOS transistor MP10, the fuse FUSE, and the resistor R as the pull-up devices and the effective resistance value of the turned-on NMOS transistor MN11 of the feedback inverter IV11 as the pull-down device should satisfy Va<ViL.

Also, referring to FIG. 5B, where the fuse FUSE is cut, the ratio between the effective resistance value of the turned-on PMOS transistor MP10 and the resistor R as the pull-up devices and the effective resistance value of the turned-on NMOS transistor MN11 of the feedback inverter IV11 as the pull-down device should satisfy Va>ViH.

VI and ViH are regulated as an input voltage Vin that defines a slope dVout/dVin of −1 in the DC characteristic curve showing the relationship of Vin and Vout of the inverter IV10. For reference, when assuming that the resistor R is connected to a general fuse circuit, a resistance value can be set approximately to 10 kΩ˜100 kΩ.

Next, in a third operation period (after the fuse state sensing period), the first fuse sensing signal IN1 maintains a logic low level, and the second fuse sensing signal IN2 transitions to a logic high level. Accordingly, the NMOS transistor MN10 maintains a turned-off state, and the PMOS transistor MP10 is turned off.

First, where the fuse FUSE is not cut, because the sensing node A transitioned to a logic high level in the second operation period that caused the output signal OUT to have a logic high level, the pull-up PMOS transistor of the feedback inverter IV11 is turned on and still maintains stably the sensing node A to a logic high level. At this time, since both ends of the fuse FUSE are connected to the resistor R, they maintain the same potential as a high level.

Where the fuse FUSE is cut, because the PMOS transistor MP10 is in a turned-off state, the sensing node A that has been maintained at a voltage level lower than the threshold logic value of the inverter IV10 during the second operation period is stabilized completely to a low level. At this time, since both ends of the fuse FUSE are connected to the resistor R, they maintain the same potential as a low level.

FIG. 3B illustrates other exemplary wave forms of the first and second fuse sensing signals IN1 and IN2 in FIG. 2. In the initialization period (the first operation period) of the fuse circuit, the first fuse sensing signal IN1 has a logic high level, and the second fuse sensing signal IN2 has a logic low level. In this case, while the NMOS transistor MN10 and the PMOS transistor MP10 are turned on, since the fuse FUSE and the resistor R are present on the pull-up path, an initialization operation where the NMOS transistor MN10 discharges the sensing node A and causes the output signal OUT to have a logic high level may be performed.

In the fuse circuit in accordance with the above embodiment of the invention, the programming state of the fuse can be stably sensed in the fuse state sensing period, and the same potential can be formed on both ends of the fuse after the fuse state sensing period, whereby electrical and chemical migration phenomena of metal ions can be originally prevented.

Hereinbelow, various embodiments will be described.

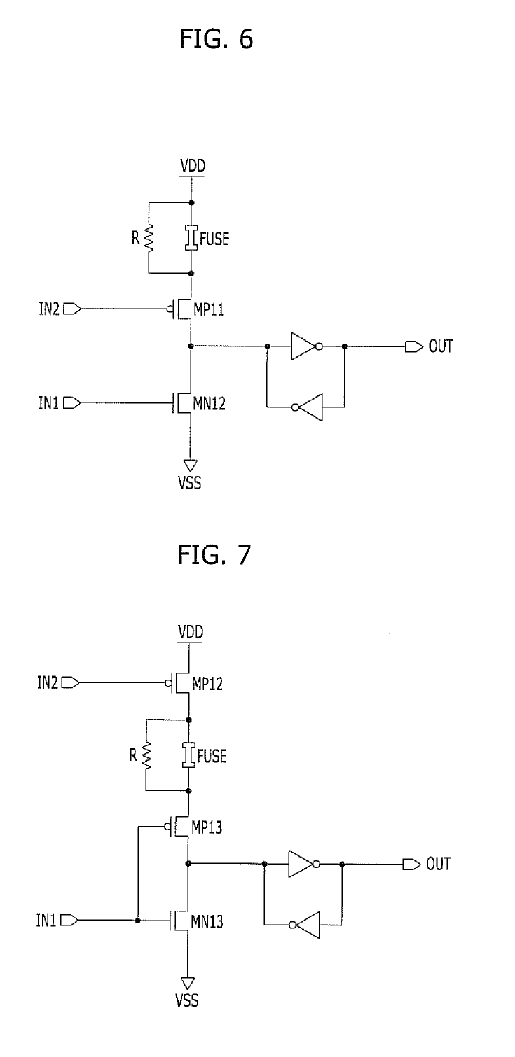

FIG. 6 is a diagram illustrating a fuse circuit in accordance with a second embodiment of the present invention.

When comparing the fuse circuit of the present embodiment with the fuse circuit of the first embodiment shown in FIG. 2, coupling positions of a PMOS transistor MP11, a fuse FUSE, and a resistor R as pull-up devices are changed. An NMOS transistor MN12 as a pull-down device is not changed.

Even in this embodiment, since only the positions of the pull-up devices are changed, the first and second fuse sensing signals IN1 and IN2 and operations of the entire fuse circuit are the same as those of the first embodiment.

FIG. 7 is a diagram illustrating a fuse circuit in accordance with a third embodiment of the present invention.

When comparing the fuse circuit of the present embodiment with the fuse circuit of the first embodiment shown in FIG. 2, a PMOS transistor MP13 to be controlled by a first fuse sensing signal IN1 is added as a pull-up device to a PMOS transistor MP12, a fuse FUSE, and a resistor R. The PMOS transistor MP13 has a source that is connected to the fuse FUSE and the resistor R, a drain that is connected to a sensing node, and a gate that receives the first fuse sensing signal IN1. An NMOS transistor MN13 as a pull-down device is not changed.

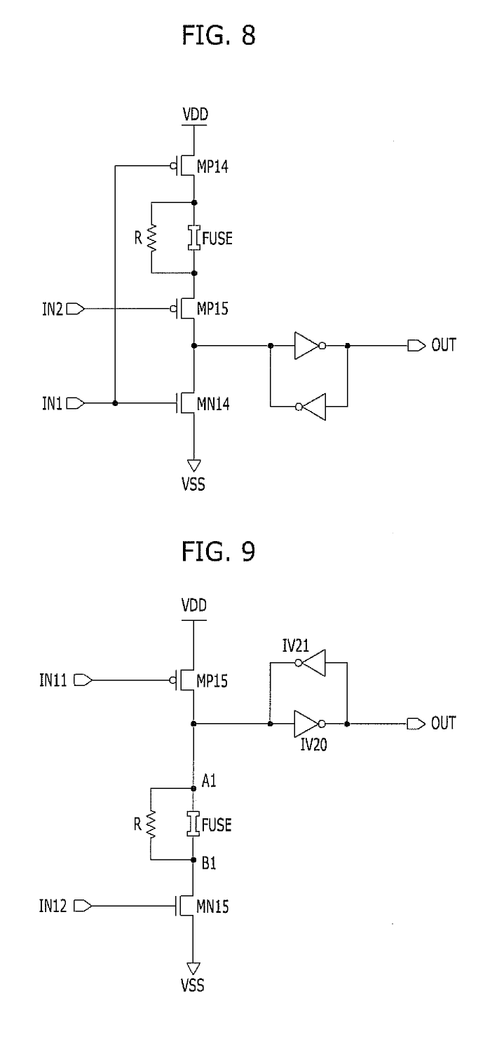

FIG. 8 is a diagram illustrating a fuse circuit in accordance with a fourth embodiment of the present invention.

Similarly to the third embodiment shown in FIG. 7, a PMOS transistor MP14 to be controlled by a first fuse sensing signal IN1 is added as a pull-up device to a PMOS transistor MP15, a fuse FUSE, and a resistor R. An NMOS transistor MN14 as a pull-down device is not changed. In the present embodiment, positions of the PMOS transistor MP14 to be controlled by the first fuse sensing signal IN1 and the PMOS transistor MP15 to be controlled by a second fuse sensing signal IN2 are set to be opposite to those of the third embodiment.

Even in the third and fourth embodiments, since one PMOS transistor to be controlled by the first fuse sensing signal IN1 is added as a pull-up device when compared to the first and second embodiments, circuit operations are substantially the same. Sizes of the respective devices should be determined by adding the effective resistance value of the PMOS transistor to the above-stated design conditions.

FIG. 9 is a diagram illustrating a fuse circuit in accordance with a fifth embodiment of the present invention.

Referring to FIG. 9, a fuse circuit in accordance with a fifth embodiment of the present invention includes a PMOS transistor MP15, an NMOS transistor MN15, a fuse FUSE, a resistors R, an inverter IV20, an inverter IN21. The PMOS transistor MP15 has a source that is connected to a power supply terminal VDD, a drain that is connected to a sensing node A1, and a gate that receives a first fuse sensing signal IN11. The NMOS transistor MN15 has a source that is connected to a ground voltage VSS, a drain that is connected to a node B1, and a gate that receives a second fuse sensing signal IN12. The fuse FUSE is connected between the sensing node A1 and a node B1. The resistor R is connected between the sensing node A1 and the node B1 in parallel to the fuse FUSE. The inverter IV20 has an input terminal that is connected to the sensing node A1 and an output terminal for outputting an output signal OUT. The inverter IV21 has an input terminal for receiving the output signal OUT and an output terminal that is connected to the sensing node A1.

The inverter IV20 and the inverter IV21 constitute an inverting latch.

When compared to the fuse circuits of the first through fourth embodiments, the fuse circuit of the fifth embodiment is distinguished in that the fuse FUSE and the resistor R are disposed not on a pull-up path but on a pull-down path.

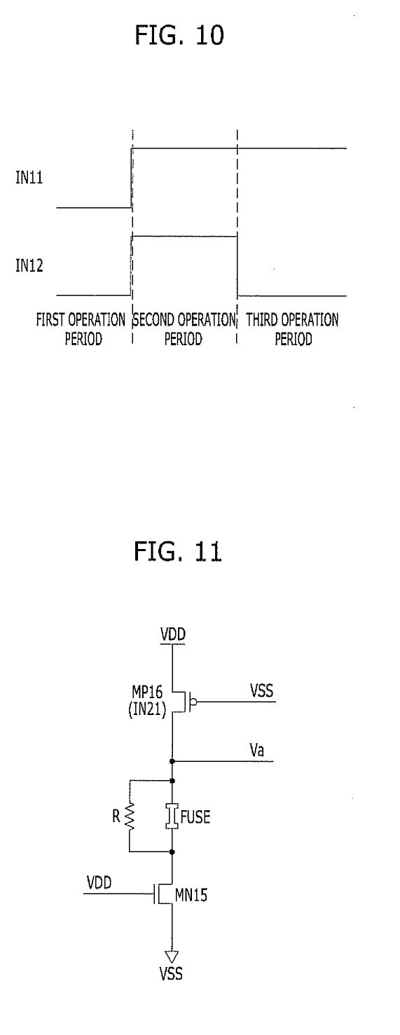

FIG. 10 is a view showing the wave forms of the first and second fuse sensing signals IN11 and IN12 in FIG. 9, and the following Table 3 represents voltage changes in the respective nodes of the fuse circuit shown in FIG. 9 depending upon the first and second fuse sensing signals IN1 and IN2 and a state of the fuse FUSE. Operations of the fuse circuit shown in FIG. 9 will be explained with reference to FIG. 10 and Table 3.

TABLE 3

| | | | | |
|---|---|---|---|---|
| | IN1 | L | H | H |
| | IN2 | L | H | L |
| Fuse No Cut | Node B1 | VDD | Vb | VSS |
| | Node A1 | VDD | Va | VSS |
| | OUT | VSS | ~VDD | VDD |
| Fuse Cut | Node B1 | VDD | Vb | VDD |
| | Node A1 | VDD | Va | VDD |
| | OUT | VSS | ~VSS | VSS |

First, in an initialization period (a first operation period) of the fuse circuit, the first and second fuse sensing signals IN11 and IN12 are both deactivated to a logic low level. At this time, the PMOS transistor MP15 is turned on to charge the sensing node A1, and the output signal OUT becomes a logic low level.

Next, in a fuse state sensing period (a second operation period) of the fuse circuit, the first and second fuse sensing signals IN11 and IN12 are both activated to a logic high level. Accordingly, the PMOS transistor MP15 is turned off and the NMOS transistor MN15 is turned on. Also, the pull-up PMOS transistor of the inverter IV21 continues driving for maintaining an initial value.

FIG. 11 shows a state of elements that determine a voltage level Va of the sensing node A1 with a fuse not cut. The NMOS transistor MN15 performs pull-down driving for the sensing node A1, and a pull-up PMOS transistor MP16 of the inverter IV21 performs pull-up driving for the sensing node A1. More specifically, transition of the sensing node A1 is effected depending upon a ratio between the effective resistance value of pull-down devices (the NMOS transistor MN15, the fuse FUSE and the resistor R) and the effective resistance value of the pull-up device (the pull-up PMOS transistor MP16 of the inverter IV21). If the voltage level Va of the sensing node A1 becomes lower than a threshold logic value ViL of the inverter IV20 (Va<ViL) for a stable operation, the output signal OUT becomes a logic high level. The output signal OUT is fed back and turns on the NMOS transistor of the inverter IV21 such that the sensing node A1 can stably maintain a logic low level. Since the resistor R is connected in parallel to the fuse FUSE, the effective resistance of the pull-down devices decreases, and thus, the connection state of the fuse FUSE may be stably sensed.

Where the fuse FUSE is cut, while both ends of the fuse FUSE are actually not in an insulated state because both ends of the fuse FUSE are connected by the resistor R, the voltage level Va of the sensing node A1 does not become unconditionally a logic high level. As described above, the voltage level Va of the sensing node A1 is determined by the ratio between the effective resistance value of the pull-down devices (the NMOS transistor MN15, the fuse FUSE and the resistor R) and the effective resistance value of the pull-up device (the pull-up PMOS transistor MP16 of the inverter IV21). As the voltage level Va of the sensing node A1 determined in this way is kept higher than the threshold logic voltage of the inverter IV20 (Va>ViH) for a stable operation, the output signal OUT becomes a logic low level and represents a the cut state of the fuse FUSE.

Next, in a third operation period (after the fuse state sensing period), the first fuse sensing signal IN1 maintains a logic high level, and the second fuse sensing signal IN2 transitions to a logic low level. Accordingly, the PMOS transistor MP15 maintains a turned-off state, and the NMOS transistor MN15 is turned off.

First, where the fuse FUSE is not cut, because the sensing node A1 transitioned to a logic low level in the second operation period that caused the output signal OUT to have a logic high level, the pull-down NMOS transistor of the feedback inverter IV21 is turned on and still maintains stably the sensing node A1 to a logic low level.

At this time, since both ends of the fuse FUSE are connected to the resistor R, they maintain the same potential as a low level.

Where the fuse FUSE is cut, because the NMOS transistor MP15 is in a turned-off state, the sensing node A1 that has been maintained at a voltage level higher than the threshold logic value of the inverter IV20 during the second operation period is stabilized completely to a high level. At this time, since both ends of the fuse FUSE are connected to the resistor R, they maintain the same potential as a high level.

In the fuse circuit in accordance with the above embodiment of the invention, the programming state of the fuse can be stably sensed in the fuse state sensing period, and the same potential can be formed on both ends of the fuse after the fuse state sensing period, whereby electrical and chemical migration phenomena of metal ions can be originally prevented.

In the fifth embodiment of the present invention, because basic operations are the same except that the pull-up device performs an initializing function, and the fuse is disposed at the side of the pull-down devices as mentioned above. The circuit may be modified in the same manner as the second through fourth embodiments.

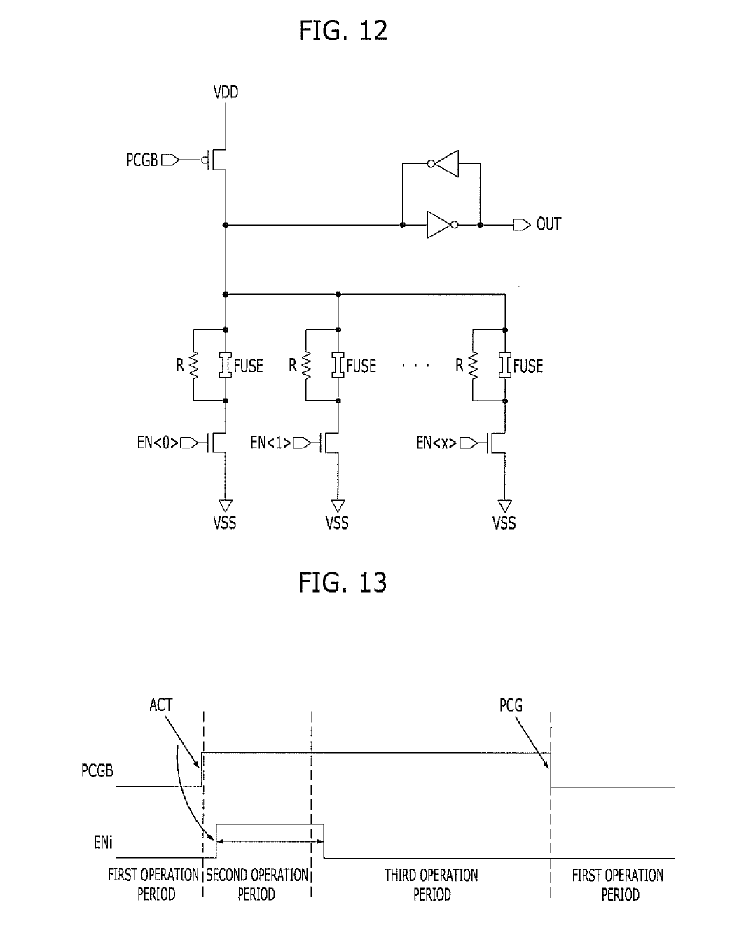

FIG. 12 is a diagram illustrating a fuse circuit in accordance with a sixth embodiment of the present invention.

Referring to FIG. 12, the fuse circuit according to the present embodiment implements a plurality of fuses that share one initialization unit (a PMOS transistor) and one sensing unit (an inverting latch). In general, a redundancy circuit of a semiconductor memory such as a DRAM may use the structure of the sixth embodiment. In particular, a fuse circuit adopting the structure of the sixth embodiment is used as a redundancy fuse that is employed in a column address access operation (read and write operations).

FIG. 13 is a view illustrating operation timings when the fuse circuit of FIG. 12 is applied to a redundancy circuit of a DRAM.

A precharge signal PCGB is a signal that is deactivated to a logic high level when an active command ACT is applied and is activated to a logic low level when a precharge command PCG is applied. Fuse enable signals EN<0:x> include row address information that is applied when the active command ACT is applied and that is assigned to a cell block generally distinguished by a bit line sense amplifier (BLSA). An example of an optional fuse enable signal ENi is activated to a logic high level by receiving the active command ACT and is deactivated to a logic low level before a column address is applied. Accordingly, the activation period of the fuse enable signal ENi is realized to be shorter than a tRCDmin (a Ras to Cas delay time), which should be ensured in a DRAM.

Because the fuse enable signals EN<0:x> are not simultaneously activated, the states of respective nodes including a fuse output terminal (the sensing node), which is commonly used, are the same as those of FIG. 9.

For reference, in FIG. 13, a first operation period corresponds to the precharged state of the DRAM, a second operation period corresponds to the active state of the DRAM, and a third operation period corresponds to a state when read and write operations can be performed.

As is apparent from the above description, in the present invention, due to the fact that the same potential is realized at both ends of a fuse without modifying a process or physically changing a fuse, the occurrence of a fail due to electrical and chemical migration phenomena of metal ions may be prevented. Also, an increase in the number of circuit elements constituting a fuse circuit may be minimized, and a circuit area is not increased.

While the present invention has been described with respect to the specific embodiments, it will be apparent to those skilled in the art that various changes and modifications may be made without departing from the spirit and scope of the invention as defined in the following claims.

For example, the logics exemplified in the above embodiments may be replaced with other logics or may be omitted, depending upon kinds and activation levels of used signals.

Also, while it was described in the above embodiments that the power supply voltage VDD is used as a pull-up voltage source and the ground voltage VSS is used as a pull-down voltage source, the present invention may be applied to a case in which these voltages being voltage sources are changed.

What is claimed is:

1. A semiconductor integrated circuit comprising:
a fuse;
a first driving unit configured to drive a sensing node in response to a first fuse sensing signal;
a second driving unit configured to drive the sensing node in response to a second fuse sensing signal, wherein the second driving unit and the fuse form a driving path;
a bypass resistor unit connected in parallel with the fuse; and
a sensing unit configured to sense a programming state of the fuse in response to a voltage of the sensing node.

2. The semiconductor integrated circuit of claim 1, wherein the first fuse sensing signal activates the first driving unit in a turn on state in a sensing node initialization period and deactivates the first driving node in a turn off state in a subsequent period.

3. The semiconductor integrated circuit of claim 2, wherein the second fuse sensing signal activates the second driving unit to a turn on state in a fuse state sensing period and deactivates the second driving unit to a turn off state in a subsequent period.

4. The semiconductor integrated circuit of claim 3, wherein the first driving unit is provided between a pull-down voltage source and the sensing node, and the second driving unit is provided between a pull-up voltage source and the sensing node.

5. The semiconductor integrated circuit of claim 3, wherein the first driving unit is provided between a pull-up voltage source and the sensing node, and the second driving unit is provided between a pull-down voltage source and the sensing node.

6. The semiconductor integrated circuit of claim 1, wherein the sensing unit includes an inverter having an input terminal that is connected to the sensing node.

7. A semiconductor integrated circuit comprising:
a fuse;
an NMOS transistor configured to pull-down drive a sensing node in response to a first fuse sensing signal;
a PMOS transistor configured to pull-up drive the sensing node in response to a second fuse sensing signal, wherein the PMOS transistor and the fuse form a driving path;
a bypass resistor unit connected in parallel with the fuse; and
a sensing unit configured to sense a programming state of the fuse in response to a voltage of the sensing node.

8. The semiconductor integrated circuit of claim 7,
wherein the fuse has a first end that is connected to the sensing node, and
wherein the PMOS transistor has a source that is connected to a pull-up voltage source, a drain that is connected to a second end of the fuse, and a gate that receives the second fuse sensing signal.

9. The semiconductor integrated circuit of claim 7,
wherein the fuse has a first end that is connected to a pull-up voltage source, and
wherein the PMOS transistor has a source that is connected to a second end of the fuse, a drain that is connected to the sensing node, and a gate that receives the second fuse sensing signal.

10. The semiconductor integrated circuit of claim 8, wherein the first fuse sensing signal is activated to a logic high level in a sensing node initialization period and transitions to a logic low level in a subsequent period.

11. The semiconductor integrated circuit of claim 10, wherein the second fuse sensing signal is activated to a logic low level in a fuse state sensing period and transitions to a logic high level in a subsequent period.

12. The semiconductor integrated circuit of claim 7, wherein the sensing unit comprises:
a first inverter having an input terminal that is connected to the sensing node; and
a second inverter configured to receive an output signal of the first inverter as an input thereof and have an output terminal that is connected to the sensing node.

13. The semiconductor integrated circuit of claim 12, wherein, when the fuse is not cut, a ratio between an effective resistance of the PMOS transistor, the bypass resistor unit, and the fuse and an effective resistance of a pull-down NMOS transistor included in the second inverter generates a voltage of the sensing node that is less than a logic low input characteristic value of the first inverter.

14. The semiconductor integrated circuit of claim 12, wherein, when the fuse is cut, a ratio between an effective resistance of the PMOS transistor and the bypass resistor unit and an effective resistance of a pull-down NMOS transistor included in the second inverter generates a voltage of the sensing node that is greater than a logic high input characteristic value of the first inverter.

15. A semiconductor integrated circuit comprising:
a fuse;
an NMOS transistor configured to pull-down drive a sensing node in response to a first fuse sensing signal;
a first PMOS transistor configured to pull-up drive the sensing node in response to a second fuse sensing signal;
a second PMOS transistor configured to pull-up drive the sensing node in response to the first fuse sensing signal, wherein the first and second PMOS transistor and the fuse form a driving path;
a bypass resistor unit connected in parallel with the fuse; and
a sensing unit configured to sense a programming state of the fuse in response to a voltage of the sensing node.

16. The semiconductor integrated circuit of claim 15,
wherein the first PMOS transistor has a source that is connected to a pull-up voltage source, a drain that is connected to a first end of the fuse, and a gate that receives the second fuse sensing signal, and
wherein the second PMOS transistor has a source that is connected to a second end of the fuse, a drain that is connected to the sensing node, and a gate that receives the first fuse sensing signal.

17. The semiconductor integrated circuit of claim 15,
wherein the second PMOS transistor has a source that is connected to a pull-up voltage source, a drain that is connected to a first end of the fuse, and a gate that receives the first fuse sensing signal, and
wherein the first PMOS transistor has a source that is connected to a second end of the fuse, a drain that is connected to the sensing node, and a gate that receives the second fuse sensing signal.

18. The semiconductor integrated circuit of claim 16, wherein the first fuse sensing signal is activated to a logic high level in a sensing node initialization period and transitions to a logic low level in a subsequent period.

19. The semiconductor integrated circuit of claim 18, wherein the second fuse sensing signal is activated to a logic low level in a fuse state sensing period and transitions to a logic high level in a subsequent period.

20. The semiconductor integrated circuit of claim 15, wherein the sensing unit comprises:
a first inverter having an input terminal that is connected to the sensing node; and
a second inverter configured to receive an output signal of the first inverter as an input thereof and have an output terminal that is connected to the sensing node.

21. The semiconductor integrated circuit of claim 20, wherein, when the fuse is not cut, a ratio between an effective resistance of the first and second PMOS transistors, the bypass resistor unit and the fuse and an effective resistance of a pull-down NMOS transistor included in the second inverter generates a voltage of the sensing node that is less than a logic low input characteristic value of the first inverter.

22. The semiconductor integrated circuit of claim 20, wherein, when the fuse is cut, a ratio between an effective resistance of the first and second PMOS transistors and the bypass resistor unit and an effective resistance of a pull-down NMOS transistor included in the second inverter generates a voltage of the sensing node that is greater than a logic high input characteristic value of the first inverter.

23. A semiconductor integrated circuit comprising:
a fuse;
a PMOS transistor configured to pull-up drive a sensing node in response to a first fuse sensing signal;
an NMOS transistor configured to pull-down drive the sensing node in response to a second fuse sensing signal, wherein the NMOS transistor and the fuse form a driving path;
a bypass resistor unit connected in parallel with the fuse; and
a sensing unit configured to sense a programming state of the fuse in response to a voltage of the sensing node.

24. The semiconductor integrated circuit of claim 23,
wherein the fuse has a first end that is connected to the sensing node, and
wherein the NMOS transistor has a source that is connected to a pull-down voltage source, a drain that is connected to a second end of the fuse, and a gate that receives the second fuse sensing signal.

25. The semiconductor integrated circuit of claim 23,
wherein the fuse has a first end that is connected to a pull-up voltage source, and
wherein the NMOS transistor has a source that is connected to a second end of the fuse, a drain that is connected to the sensing node, and a gate that receives the second fuse sensing signal.

26. The semiconductor integrated circuit of claim 24, wherein the first fuse sensing signal is activated to a logic low level in a sensing node initialization period and transitions to a logic high level in a subsequent period.

27. The semiconductor integrated circuit of claim 26, wherein the second fuse sensing signal is activated to a logic high level in a fuse state sensing period and transitions to a logic low level in a subsequent period.

28. The semiconductor integrated circuit of claim 23, wherein the sensing unit comprises:
a first inverter having an input terminal that is connected to the sensing node; and
a second inverter configured to receive an output signal of the first inverter as an input thereof and have an output terminal that is connected to the sensing node.

29. The semiconductor integrated circuit of claim 28, wherein, when the fuse is not cut, a ratio between an effective resistance of the NMOS transistor, the bypass resistor unit and the fuse and an effective resistance of a pull-up PMOS transistor included in the second inverter generates a voltage of the sensing node that is less than a logic low input characteristic value of the first inverter.

30. The semiconductor integrated circuit of claim 28, wherein, when the fuse is cut, a ratio between an effective resistance of the NMOS transistor and the bypass resistor unit and an effective resistance of a pull-up PMOS transistor included in the second inverter generates a voltage of the sensing node that is greater than a logic high input characteristic value of the first inverter.

31. A semiconductor integrated circuit comprising:
a fuse;
a PMOS transistor configured to pull-up drive a sensing node in response to a first fuse sensing signal;
a first NMOS transistor configured to pull-down drive the sensing node in response to a second fuse sensing signal;
a second NMOS transistor the first NMOS transistor and configured to pull-down drive the sensing node in response to the first fuse sensing signal, wherein the first and second NMOS transistor and the fuse form a driving path;
a bypass resistor unit connected between both ends of the fuse; and
a sensing unit configured to sense a programming state of the fuse in response to a voltage of the sensing node.

32. The semiconductor integrated circuit of claim 31,
wherein the first NMOS transistor has a source that is connected to a pull-down voltage source, a drain that is connected to a first end of the fuse, and a gate that receives the second fuse sensing signal, and
wherein the second NMOS transistor has a source that is connected to a second end of the fuse, a drain that is connected to the sensing node, and a gate that receives the first fuse sensing signal.

33. The semiconductor integrated circuit of claim 31,
wherein the second NMOS transistor has a source that is connected to a pull-down voltage source, a drain that is connected to a first end of the fuse, and a gate that receives the first fuse sensing signal, and
wherein the first NMOS transistor has a source that is connected to a second end of the fuse, a drain that is connected to the sensing node, and a gate that receives the second fuse sensing signal.

34. The semiconductor integrated circuit of claim 32, wherein the first fuse sensing signal is activated to a logic low level in a sensing node initialization period and transitions to a logic high level in a subsequent period.

35. The semiconductor integrated circuit of claim 34, wherein the second fuse sensing signal is activated to a logic high level in a fuse state sensing period and transitions to a logic low level in a subsequent period.

36. The semiconductor integrated circuit of claim 31, wherein the sensing unit comprises:
a first inverter having an input terminal that is connected to the sensing node; and
a second inverter configured to receive an output signal of the first inverter as an input thereof and have an output terminal that is connected to the sensing node.

37. The semiconductor integrated circuit of claim 36, wherein, when the fuse is not cut, a ratio between an effective resistance of the first and second NMOS transistors, the bypass resistor unit and the fuse and an effective resistance of a pull-up PMOS transistor included in the second inverter generates a voltage of the sensing node that is less than a logic low input characteristic value of the first inverter.

38. The semiconductor integrated circuit of claim 36, wherein, when the fuse is cut, a ratio between an effective resistance of the first and second NMOS transistors and the bypass resistor unit and an effective resistance of a pull-up PMOS transistor included in the second inverter generates a voltage of the sensing node that is greater than a logic high input characteristic value of the first inverter.

39. A semiconductor memory device comprising:
a plurality of fuses;
a first driving unit configured to pull-up drive a common sensing node in response to a precharge signal;
a plurality of second driving units configured to pull-down drive the common sensing node in response to corresponding address information, wherein the plurality of second driving units and corresponding fuses form driving paths;
a plurality of bypass resistor units connected in parallel with corresponding fuses; and
a sensing unit configured to sense a programming state of each of the plurality of fuses in response to a voltage of the common sensing node.

40. The semiconductor integrated circuit of claim 39, wherein the precharge signal is activated by receiving a precharge command and is deactivated by receiving an active command.

41. The semiconductor integrated circuit of claim 40, wherein the respective address informations are sequentially activated by receiving the active command, and an activation period is shorter than tRCDmin (a minimum value of a Ras to Cas delay time).
